(19) United States
(12) Patent Application Publication
(10) Pub. No.: US 2005/0207116 A1
(43) Pub. Date: Sep. 22, 2005

(54) Systems and methods for inter-cooling computer cabinets

(76) Inventors: Alexander I. Yatskov, Seattle, WA (US); Douglas P. Kelley, Seattle, WA (US)

Correspondence Address: PERKINS COIE LLP;PATENT-SEA, P.O. BOX 1247, SEATTLE, WA, 98111-1247, US

(21) Appl. No.: 10/805,875

(22) Filed: Mar. 22, 2004

(51) Int. Cl. H05K 7/20

(52) U.S. Cl. 361/690; 361/701; 454/184; 165/80.3

(57) ABSTRACT

Systems and methods for cooling computer components housed in cabinets in large computer systems are disclosed herein. In one embodiment, a computer system configured in accordance with the present invention includes a chassis having at least first and second computer module compartments. The first and second computer module compartments are positioned in an air flow path in the chassis. In this embodiment, the computer system further includes a heat exchanger positioned in the air flow path in the chassis at least partially downstream of the first computer module compartment and at least partially upstream of the second computer module compartment. A computer system configured in accordance with another embodiment of the invention includes a heat exchanger positioned at least proximate to a first computer module compartment in an air flow path. The heat exchanger can include at least one internal fluid passage configured to carry a working fluid in phase transition.

### TECHNICAL FIELD

The following disclosure relates generally to systems and methods for cooling computer components and, more particularly, to systems and methods for cooling high density computer components housed in cabinets in large computer systems.

### BACKGROUND

Supercomputers and other large computer systems typically include a large number of processors housed in cabinets arranged in banks. FIG. 1, for example, illustrates a large computer system 100 configured in accordance with the prior art. The computer system 100 includes a plurality of computer cabinets 102 situated on a floor 103. Each of the computer cabinets 102 contains a plurality of computer modules 106 arranged horizontally in close proximity to each other. Each of the modules 106 can include a motherboard carrying one or more processors, buses, and associated memory. The modules 106 are positioned in close proximity to each other in a high density arrangement in the computer cabinets 102 for a number of reasons. One reason is that close proximity can increase computational performance by increasing signal speed and reducing signal decay. Another reason is that close proximity can reduce cable cost and routing complexity. One downside of such an arrangement, however, is that the modules 106 can generate considerable heat during operation that should be dissipated to avoid damaging the modules 106 or significantly reducing performance.

To dissipate the heat generated by the computer modules 106, the computer system 100 further includes an air-conditioning unit 110. The air-conditioning unit 110 includes a cooling coil 112 and two air movers 114. In operation, the air-conditioning unit 110 draws in warm air from around the computer cabinets 102 and cools the air before flowing it into a plenum 104 extending beneath the floor 103. The plenum 104 distributes the high pressure cooling air to a plurality of floor outlets 116 positioned between the computer cabinets 102. Cooling fans (not shown) positioned on the computer cabinets 102 move the cooling air from the floor outlets 116 through the computer cabinets 102 to cool the modules 106. Warm air from the computer cabinets 102 then circulates back to the air-conditioning unit 110 as part of a continual cooling cycle.

One shortcoming associated with the conventional air conditioning system described above with reference to FIG. 1 is the limited ability to sufficiently cool all of the computer modules 106. The ability to cool is limited because the close proximity of the computer cabinets 102 causes warm exhaust air from one cabinet to flow into an adjacent cabinet. Further, some locations in the computer cabinets 102 are typically hotter than others during operation of the computer system 100 as a result of (a) particularly high power densities and/or (b) poor positioning with respect to the flow of cooling air. One way to increase the cooling capacity of the prior art computer system 100 is to reduce the temperature of the cooling air. This approach is often impractical, however, because it frequently requires lowering the temperature below the dew point in the air-conditioning unit 110, which causes water vapor to condense out of the air. The removal of water vapor can lower the relative humidity to such a point that it introduces electrostatic discharge concerns. Further, it can require the addition of water vapor at other locations in the facility to increase the relative humidity.

Another way to increase the cooling capacity of such a system is to increase the flow rate of cooling air from the air-conditioning unit 110. This approach is often impractical as well, because it can require larger fans, increased coolant flows, and higher power requirements than the facility was originally designed to accommodate. Further, it can also result in turbulent air flow. The heat transfer capability of turbulent air flow approaches an upper limit as the flow rate is increased. As a result, increasing the flow rate beyond a certain point may not increase the cooling capacity of the air flow.

### BRIEF DESCRIPTION OF THE DRAWINGS

FIG. 1 illustrates a large computer system configured in accordance with the prior art.

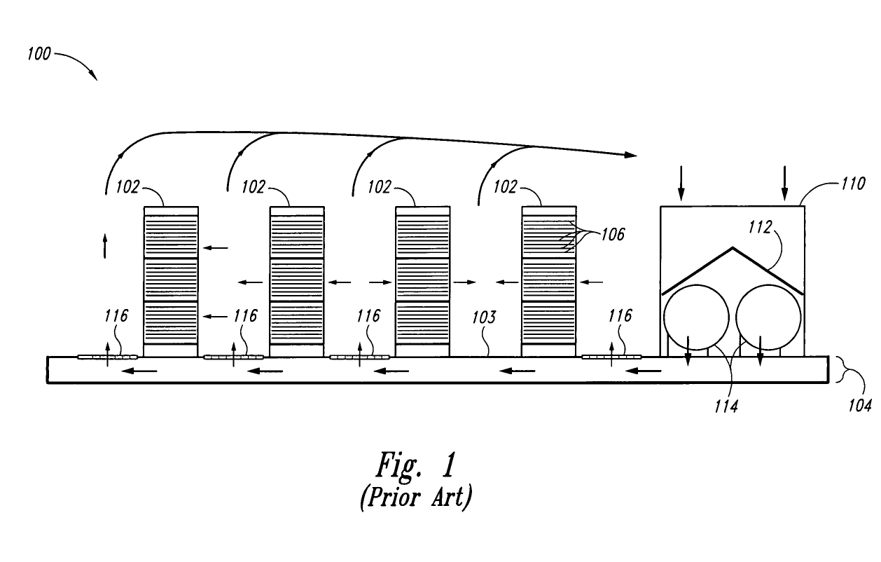

FIG. 2 is a partially schematic isometric view of a computer system having a computer cabinet with inter-cooled computer module compartments configured in accordance with an embodiment of the invention.

FIG. 3 is an enlarged front isometric view of a portion of the computer cabinet of FIG. 2 illustrating aspects of the computer module compartments configured in accordance with an embodiment of the invention.

FIG. 4 is a partially hidden, rear isometric view of the computer system of FIG. 2 configured in accordance with an embodiment of the invention.

FIG. 5 is a partially hidden top view of a heat exchanger configured in accordance with an embodiment of the invention.

FIGS. 6A-6B illustrate computer cabinets configured in accordance with other embodiments of the invention.

### DETAILED DESCRIPTION

The following disclosure describes several embodiments of systems and methods for cooling high density computer modules in large computer systems. One aspect of the invention is directed toward a computer system that includes a chassis having at least first and second computer module compartments. The first and second computer module compartments are positioned in an air flow path in the chassis. In one aspect of this embodiment, the computer system further includes a heat exchanger positioned at least partially downstream of the first computer module compartment and at least partially upstream of the second computer module compartment. In another aspect of this embodiment, the computer system further includes an air mover configured to move air along the air flow path in the chassis through the first computer module compartment, past the heat exchanger, and through the second computer module compartment.

A computer system configured in accordance with another aspect of the invention includes a chassis and a first computer compartment positioned in an air flow path in the chassis. In one aspect of this embodiment, the computer system further includes a heat exchanger positioned at least proximate to the first computer module compartment in the air flow path. The heat exchanger includes at least one internal fluid passage configured to carry a working fluid having a boiling temperature in the heat exchanger between about 45° F. and about 75° F. In another aspect of this embodiment, a first portion of the working fluid is in a liquid state and a second portion of the working fluid is in a vapor or gaseous (hereinafter gaseous) state in the heat exchanger.

A method for cooling first and second computer modules in a common chassis in accordance with a further aspect of the invention includes moving a portion of air past the first computer module to transfer heat from the first computer module to the portion of air. After moving the portion of air past the first computer module, the method further includes moving the portion of air past a heat exchanger within the chassis to transfer heat from the portion of air to the heat exchanger. After moving the portion of air past the heat exchanger, the method additionally includes moving the portion of air past the second computer module to transfer heat from the second computer module to the portion of air.

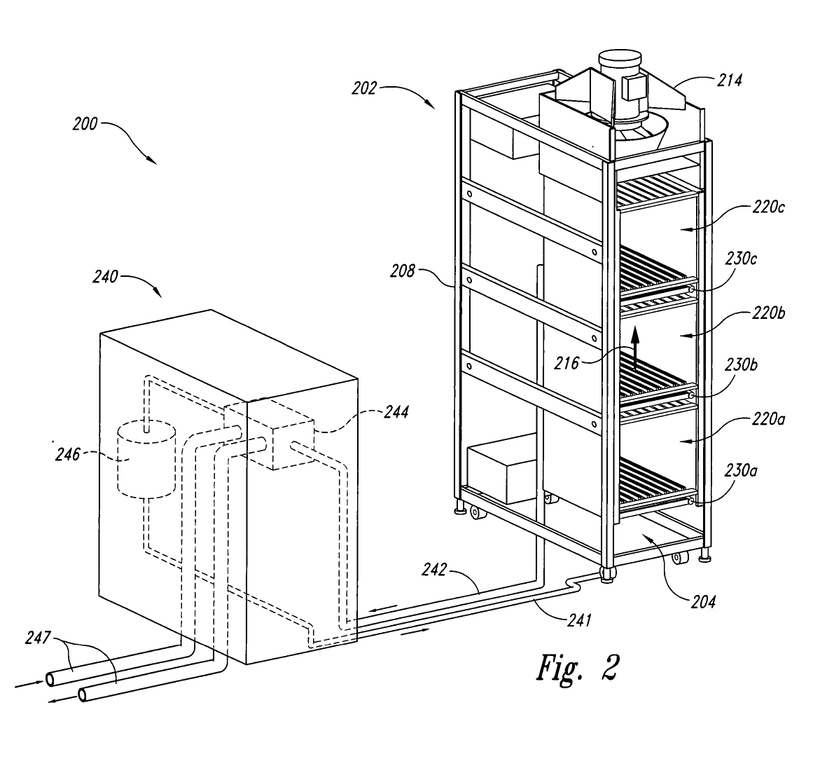

Specific details of several embodiments of the invention are described below to provide a thorough understanding of such embodiments. However, other details describing well-known structures often associated with large computer systems and air conditioning systems for large computer systems are not set forth below to avoid unnecessarily obscuring the description of the various embodiments. Further, those of ordinary skill in the art will understand that the invention may have other embodiments that include additional elements or lack one or more of the elements described below with reference to FIGS. 2-6B.

In the Figures, identical reference numbers identify identical or at least generally similar elements. To facilitate the discussion of any particular element, the most significant digit or digits of any reference number refer to the Figure in which that element is first introduced. For example, element 210 is first introduced and discussed with reference to FIG. 2.

FIG. 2 is a partially schematic isometric view of a computer system 200 having a heat removal system 240 and a computer cabinet 202 configured in accordance with an embodiment of the invention. In one aspect of this embodiment, the computer cabinet 202 includes a plurality of computer module compartments 220 (identified individually as a first computer module compartment 220a, a second computer module compartment 220b, and a third computer module compartment 220c) arranged vertically in a chassis 208. As described in greater detail below, each of the computer module compartments 220 (“module compartments 220”) is configured to support a plurality of computer modules oriented edgewise in a high density arrangement with respect to an air flow path 216. The computer modules are not shown in FIG. 2 for purposes of clarity. In addition, the computer cabinet 202 can also include one or more exterior panels or covers that are also not shown in FIG. 2 for purposes of clarity.

In another aspect of this embodiment, the computer cabinet 202 further includes a plurality of heat exchangers 230 (identified individually as a first heat exchanger 230a, a second heat exchanger 230b, and a third heat exchanger 230c) positioned in the air flow path 216. As described in greater detail below, each of the heat exchangers 230 can be configured to circulate a working fluid (not shown) received from the heat removal system 240 via an inlet line 241. After circulating through the heat exchangers 230, the working fluid returns to the heat removal system 240 via an outlet line 242.

In one embodiment described in greater detail below, the working fluid can include a refrigerant in phase transition from a liquid to a gas. In this embodiment, the working fluid passes through a condenser 244 and a pump 246 (both shown schematically in FIG. 2) after returning to the heat removal system 240. The condenser 244 cools the returning working fluid and condenses it from the gaseous state to the liquid state. The condenser 244 can utilize a chilled-water circuit 247 for this purpose. In other embodiments, other types of condensers and/or refrigeration systems can be used to condense working fluid. The pump 246 circulates the working fluid back to the heat exchangers 230 via the inlet line 241. The static pressure of the working fluid is controlled to maintain the working fluid in phase transition at least through the heat exchangers 230.

In a further aspect of this embodiment, the computer cabinet 202 additionally includes a fan or air mover 214 positioned toward an upper portion of the chassis 208. In operation, the air mover 214 draws air into the chassis 208 through an inlet region 204 positioned toward a bottom portion of the computer cabinet 202. The first heat exchanger 230a cools the air moving into the chassis 208 through the inlet region 204 before the air flows into the first module compartment 220a. As the air flows through the first module compartment 220a, the computer modules (not shown) in the first module compartment 220a transfer heat to the air. However, the second heat exchanger 230b cools the air before the air passes into the second module compartment 220b. This inter-cooling enables the air to efficiently cool the computer modules (not shown) in the second module compartment 220b. The air is similarly inter-cooled by the third heat exchanger 230c before passing into the third module compartment 220c.

One advantage of the inter-cooling system described above in accordance with the present invention is that it can efficiently cool a plurality of computer modules in a high density arrangement with a relatively moderate air flow. Another advantage of this system is that the temperatures of the heat exchangers 230 and the cooling air do not drop below the dew point. As a result, the computer modules are efficiently cooled without condensation forming on the heat exchangers 230 and/or the computer modules, which could result in damage to the modules and/or associated hardware.

Although FIG. 2 illustrates one embodiment of an inter-cooling system configured in accordance with the present invention, modifications can be made to the embodiment of FIG. 2 without departing from the spirit or scope of the present invention. For example, as described in greater detail below, in another embodiment the air mover 214 can be positioned toward a bottom portion of the computer cabinet 202 and configured to blow upwardly through the chassis 208. In a further embodiment, the air mover 214 can be omitted, and a remote air conditioning system can provide conditioned air to the computer cabinet 202 via a floor plenum or other ducting system.

Only a single computer cabinet 202 is presented in FIG. 2 for purposes of illustration and ease of reference. In other embodiments, however, supercomputers and other large computer systems can include a plurality of the computer cabinets 202 arranged in banks or other configurations. In such embodiments, the heat removal system 240 can provide working fluid to one or more of the computer cabinets 202 via an appropriately configured piping circuit. Further, although the heat exchangers 230 have been described above in the context of working fluid-type heat exchangers, in other embodiments, other types of heat exchangers can be used to inter-cool the air moving through the module compartments 220 without departing from the spirit or scope of the present invention. For example, in one other embodiment, a heat sink-type heat exchanger that operates in the absence of a circulating working fluid can be used. Such a heat exchanger, however, would presumably be less efficient than the working fluid-type heat exchangers described above with reference to FIG. 2.

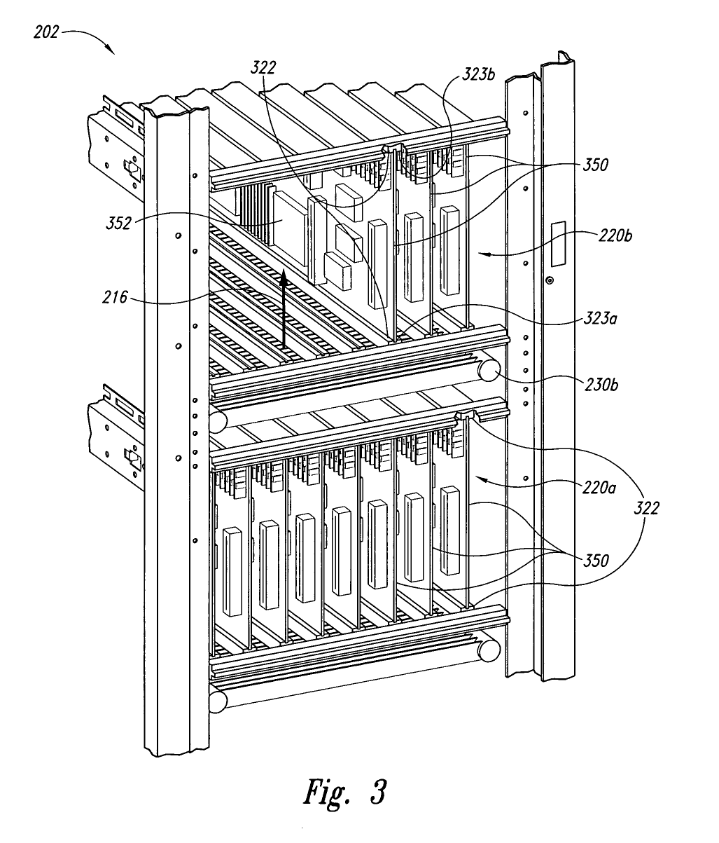

FIG. 3 is an enlarged front isometric view of a portion of the computer cabinet 202 illustrating aspects of the first and second module compartments 220a-b configured in accordance with an embodiment of the invention. In one aspect of this embodiment, the first module compartment 220a includes a plurality of module guide sets 322 arranged in parallel below the second heat exchanger 230b. Similarly, the second module compartment 220b includes a corresponding plurality of module guide sets 322 arranged in parallel above the second heat exchanger 230b. Each of the module guide sets 322 includes a lower guide 323a and a corresponding upper guide 323b. The upper and lower guides 323a-b in each set cooperate to releasably hold a corresponding computer module 350 in edge-wise orientation relative to the air flow path 216. Each of the computer modules 350 can include one or more processors 352 in addition to other electrical components and circuitry. In the illustrated embodiment, each of the module compartments 220 are configured to hold eight of the computer modules 350. In other embodiments, the module compartments 220 can hold more or fewer computer modules depending on various factors such as cabinet size, module size, and proximity requirements.

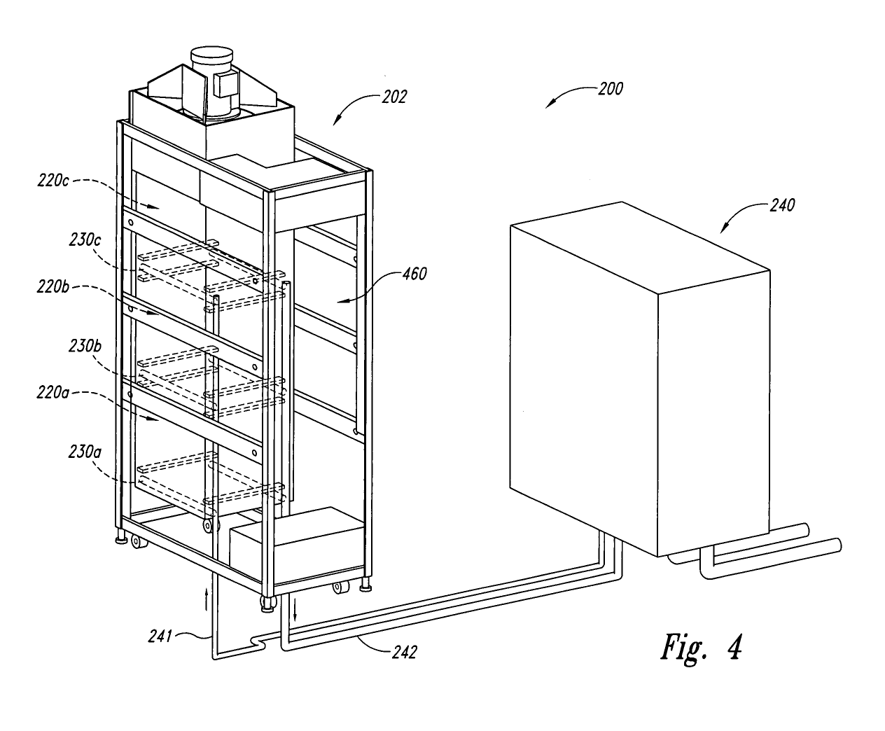

FIG. 4 is a partially hidden, rear isometric view of the computer system 200 of FIG. 2 configured in accordance with an embodiment of the invention. In one aspect of this embodiment, the computer cabinet 202 includes a cable management region 460 located behind the module compartments 220. The cable management region 460 provides space for routing various power and data cables (not shown) from the computer modules 350 (FIG. 3) to related hardware. The fluid inlet line 241 extends upwardly along one side of the cable management region 460 to provide the working fluid from the heat removal system 240 to each of the heat exchangers 230. Similarly, the fluid outlet line 242 extends downwardly along an opposite side of the cable management region 460 to return the working fluid from the heat exchangers 230 to the heat removal system 240.

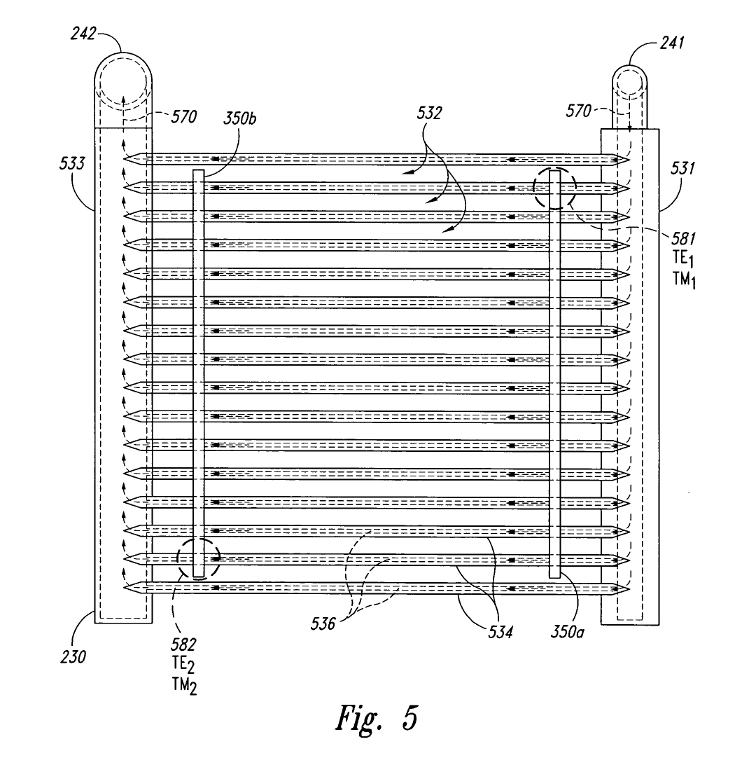

FIG. 5 is a partially hidden top view of one of the heat exchangers 230 configured in accordance with an embodiment of the invention. In one aspect of this embodiment, the heat exchanger 230 includes a plurality of cooling fins 534 extending between an inlet manifold 531 and an outlet manifold 533. The inlet manifold 531 is configured to receive working fluid (identified by arrows 570) from the fluid inlet line 241. The outlet manifold 533 is configured to return the working fluid 570 to the fluid outlet line 242. Each of the cooling fins 534 can include an internal fluid passage or microchannel 536 configured to carry the working fluid 570 from the inlet manifold 531 to the outlet manifold 533. The cooling fins 534 are spaced apart from each other to create openings 532 through which air moving along the flow path 216 (FIGS. 2 and 3) can pass. As the air flows through the openings 532, the working fluid 570 absorbs heat from the air, thereby cooling the air before it moves on to the next module compartment 220 (FIGS. 2-4). The working fluid 570 absorbs heat very efficiently because the cooling fins 534 have very thin walls and are relatively thin themselves, thereby avoiding significant pressure drops in the air flow.

A number of different types of working fluid 570 can be used with the heat exchanger 230 in various embodiments of the invention. For example, in one embodiment, the working fluid 570 can be largely composed of water. In another embodiment, the working fluid 570 can include a refrigerant in a fully evaporated state. In a further embodiment, the working fluid 570 can include a refrigerant or other fluid that transitions from a liquid state to a gaseous state in the heat exchanger 230. When using a working fluid in phase transition, a first portion of the fluid is in a first state, such as a liquid state, and a second portion of the fluid is in a second state, such as a gaseous state. That is, when the working fluid is in phase transition, two states coexist in a single chamber.

Two computer modules 350 (identified individually as a first computer module 350a and a second computer module 350b) are illustrated in FIG. 5 to facilitate a comparison of the different types of working fluids mentioned above. For purposes of discussion, the temperature of the first computer module 350a at a first location 581 is identified as TM₁, and the corresponding temperature of the heat exchanger 230 at this location is identified as TE₁. In addition, the temperature of the second computer module 350b at a second location 582 is identified as TM₂, and the corresponding temperature of the heat exchanger 230 at this location is identified as TE₂. By way of example, the first location 581 is assumed to encompass a relatively cool spot on the first computer module 350a, and the second location 582 is assumed to encompass a relatively hot spot on the second computer module 350b. Accordingly, TM₂ is greater than TM₁ in this example.

If water is used for the working fluid 570, the temperature of the water will rise as it flows from the inlet manifold 531 to the outlet manifold 533 because of the heat transfer from the warm air flowing through the openings 532. Accordingly, TE₂ will be somewhat higher than TE₁ when using water as the working fluid. As a result, the heat exchanger 230 may not be able to adequately cool the second computer module 350b at the relatively hot second location 582 unless the temperature of the water coming into the inlet manifold 531 is sufficiently reduced. Reducing the temperature of the incoming water to such a level, however, may overcool the first location 581 causing condensation to form on the heat exchanger 230 and/or the first computer module 350a at this location. The use of water as the working fluid 570 also increases the risk of damage from a leak because, unlike pressurized refrigerant, leaking water will not evaporate and instead may drip onto the computer modules.

If a fully evaporated refrigerant (i.e., a refrigerant in a fully gaseous state) is used for the working fluid 570, the entire surface of the heat exchanger 230 will draw heat from the air flow regardless of the local air temperature. As a result, this type of refrigerant may lower the local air temperature at the relatively cool first location 581 to such a point that condensation forms on the first computer module 350a and/or the heat exchanger 230 at this location.

If a refrigerant in phase transition is used as the working fluid 570, the refrigerant will absorb heat from the air only if the air temperature is above the boiling point of the refrigerant. If the air temperature is below the boiling point, the air will cool the refrigerant, causing some of the gaseous portion to condense into liquid. Either way, as the refrigerant changes phase, it does so at a constant temperature such that TE₂ will be equal to TE₁ when using a refrigerant in phase transition as the working fluid 570. Thus, a refrigerant in phase transition can adequately cool the second computer module 350b at the relatively hot second location 582 without overcooling the first computer module 350a at the relatively cool first location 581. In one embodiment, for example, a refrigerant having a boiling temperature of between about 45° F. and about 75° F. can be used as the working fluid 570. In another embodiment, the refrigerant R134A, having a boiling temperature of between about 50° F. and about 65° F. (e.g., about 55° F.) can be used as the working fluid 570. In a further aspect of this embodiment, the boiling point of such a refrigerant can be controlled by controlling the static pressure, subcooling the refrigerant, or increasing the condensing capacity of the condenser 244 with the heat removal system 240 (FIGS. 2 and 4).

One advantage of using a refrigerant in phase transition is that the temperature of the heat exchanger 230 remains at least approximately constant across the entire heat exchanger. As explained above, this allows the temperature of the heat exchanger 230 to be sufficiently low enough to cool the “hot” second location 582 without resulting in condensation at the “cool” first location 581. A further advantage of this type of working fluid is that, in the event of a leak, the working fluid will simply evaporate without damaging any adjacent hardware. Further, because a possible leak is of less concern, the walls of the cooling fins 534 can be made relatively thin, thereby enhancing their heat transfer capability without resulting in a significant pressure drop in the air flow.

Another advantage of the inter-cooling system described above is that it eliminates plenums, such as floor plenums, for distributing high-pressure cooling air to a plurality of computer cabinets. Large plenums often result in non-uniform and turbulent airflow that does not provide even cooling to all cabinets located in a large room. The inter-cooling system described above eliminates the non-uniformity associated with a large plenum system. By doing so it also reduces facility costs associated with such plenums. Further, it eliminates the need for large air movers to supply high pressure cooling air to the plenums for distribution to the cabinets. Eliminating these air movers reduces noise in the computer room and power requirements. Further, it conserves floor space for additional computer cabinets and increases the efficiency of the overall system.

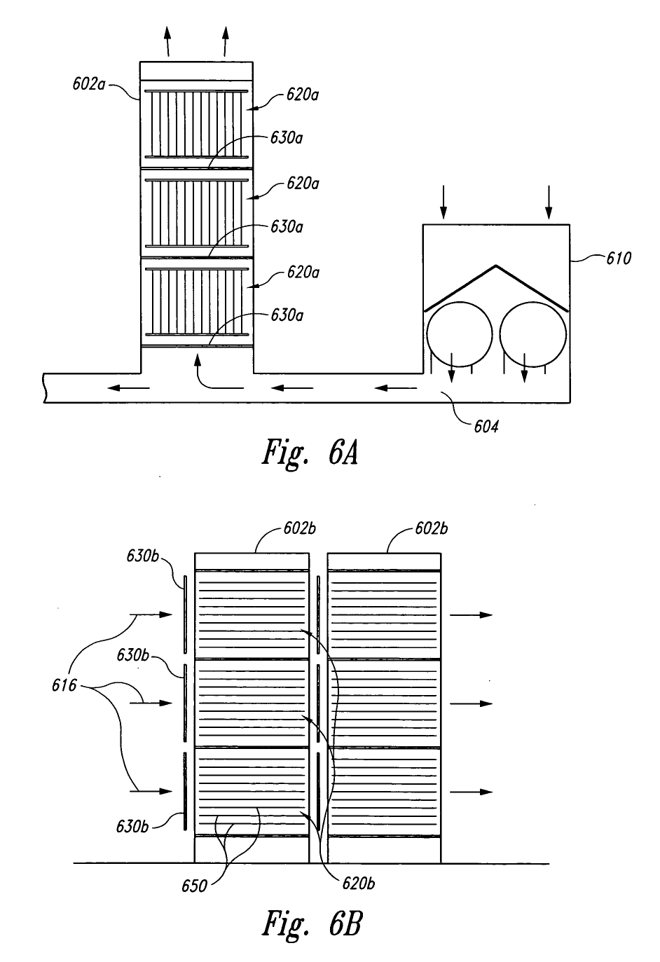

FIGS. 6A-6B illustrate computer cabinets 602a and 602b, respectively, configured in accordance with other embodiments of the invention. Referring first to FIG. 6A, in one aspect of this embodiment, the computer cabinet 602a includes a plurality of heat exchangers 630a inter-spaced between corresponding computer module compartments 620a. The module compartments 620a and the heat exchangers 630a can be at least generally similar in structure and function to their counterparts described above with reference to FIGS. 2-5. In another aspect of this embodiment, however, the computer cabinet 602a lacks a dedicated air mover. In this embodiment, a remote air conditioning system 610 provides air to the computer cabinet 602a via a floor plenum 604. In operation, air from the surrounding room flows into the air conditioning system 610 and is cooled. The cooled air then flows from the air conditioning system 610 through the floor plenum 604 and into a bottom portion of the computer cabinet 602a. From there, the air flows upwardly through the module compartments 620a and past the corresponding heat exchangers 630a before being exhausted through an upper portion of the computer cabinet 602a.

Referring next to FIG. 6B, in one aspect of this embodiment, the computer cabinet 602b includes a plurality of computer module compartments 620b configured to hold a plurality of computer modules 650 oriented horizontally with respect to an incoming air flow path 616. In one aspect of this embodiment, the computer cabinet 602b further includes a plurality of heat exchangers 630b positioned toward one side of the computer cabinet 602b and upstream of the computer modules 650. In operation, air flowing along the air flow path 616 is cooled by the heat exchangers 630b before passing over the corresponding computer modules 650. As further illustrated in FIG. 6B, a plurality of computer cabinets 602b can be arranged side-by-side in banks, with sufficient cooling of the corresponding computer modules 650 by way of the heat exchangers 630b.

From the foregoing, it will be appreciated that specific embodiments of the invention have been described herein for purposes of illustration, but that various modifications may be made without deviating from the spirit and scope of the invention. Accordingly, the invention is not limited except as by the appended claims.

1. A computer system comprising:
a chassis;
a first computer module compartment positioned in the chassis and in an air flow path;
a second computer module compartment positioned in the chassis and in the air flow path; and
a heat exchanger positioned in the chassis and in the air flow path.

2. The computer system of claim 1 wherein the heat exchanger is positioned at least partially downstream of the first computer module compartment and at least partially upstream of the second computer module compartment.

3. The computer system of claim 1 wherein the heat exchanger includes at least one internal fluid passage configured to carry a working fluid.

4. The computer system of claim 1 wherein the heat exchanger includes at least one internal fluid passage configured to carry a working fluid having a boiling point in the heat exchanger between about 45° F. and about 75° F.

5. The computer system of claim 1 wherein the heat exchanger includes at least one opening through which air can pass from at least proximate the first computer module compartment to at least proximate the second computer module compartment.

6. The computer system of claim 1 wherein the heat exchanger is positioned at least partially between the first and second computer module compartments in the chassis.

7. The computer system of claim 1 wherein the heat exchanger is a first heat exchanger, and wherein the computer system further comprises:
a third computer module compartment positioned in the chassis and in the air flow path; and
a second heat exchanger positioned in the chassis and in the air flow path, wherein the second heat exchanger is positioned at least partially downstream of the second computer module compartment and at least partially upstream of the third computer module compartment.

8. The computer system of claim 1 wherein the heat exchanger is a first heat exchanger, and wherein the computer system further comprises:
a third computer module compartment positioned in the chassis and in the air flow path; and
a second heat exchanger positioned in the chassis and in the air flow path, wherein the second heat exchanger is positioned at least partially downstream of the second computer module compartment and at least partially upstream of the third computer module compartment, wherein the first, second, and third computer module compartments, and the first and second heat exchangers, are arranged vertically in the chassis.

9. The computer system of claim 1 wherein the first computer module compartment, the second computer module compartment, and the heat exchanger are arranged vertically in the chassis.

10. The computer system of claim 1 wherein the first computer module compartment is configured to hold at least a first computer module oriented edgewise with respect to the air flow path.

11. The computer system of claim 1 wherein the first computer module compartment is configured to hold a plurality of computer modules oriented edgewise with respect to the air flow path.

12. The computer system of claim 1 wherein the first computer module compartment is configured to hold at least a first computer module oriented edgewise with respect to the air flow path toward a first side of the heat exchanger, and wherein the second computer module compartment is configured to hold at least a second computer module oriented edgewise with respect to the air flow path toward a second side of the heat exchanger opposite to the first side of the heat exchanger.

13. The computer system of claim 1, further comprising:
a first computer module carried by the first computer module compartment, wherein the first computer module includes at least a first computer processor; and
a second computer module carried by the second computer module compartment, wherein the second computer module includes at least a second computer processor.

14. The computer system of claim 1, further comprising an air mover configured to move air past the heat exchanger along the air flow path in the chassis.

15. The computer system of claim 1, further comprising an air mover carried by the chassis and configured to move air past the heat exchanger along the air flow path in the chassis.

16. A computer system comprising:
a chassis;
a first computer module compartment positioned in the chassis and in an air flow path; and
a heat exchanger positioned at least proximate to the first computer module compartment and in the air flow path, the heat exchanger including at least one internal fluid passage configured to carry a working fluid having a boiling point in the heat exchanger between about 45° F. and about 75° F.

17. The computer system of claim 16 wherein the first computer module compartment is configured to hold a plurality of computer modules oriented edgewise with respect to the air flow path.

18. The computer system of claim 16 wherein the first computer module compartment is position at least proximate to a first side of the heat exchanger, and wherein the chassis further includes a second computer module compartment positioned in the air flow path in the chassis at least proximate to a second side of the heat exchanger opposite to the first side of the heat exchanger.

19. The computer system of claim 16 wherein the heat exchanger is a first heat exchanger, and wherein the computer system further comprises:
a third computer module compartment positioned in the air flow path in the chassis; and
a second heat exchanger positioned at least partially between the second and third computer module compartments in the air flow path in the chassis, the second heat exchanger including at least one internal fluid passage configured to carry a working fluid having a boiling point in the second heat exchanger between about 45° F. and about 75° F.

20. The computer system of claim 16, further comprising an air mover configured to move air through at least one opening in the heat exchanger along the air flow path in the chassis.

21. The computer system of claim 16, further comprising the working fluid, wherein the working fluid is carried by the internal fluid passage of the heat exchanger.

22. The computer system of claim 16, further comprising the working fluid, wherein the working fluid is carried by the internal fluid passage of the heat exchanger, and wherein a first portion of the working fluid is in a liquid state and a second portion of the working fluid is in a gaseous state in the heat exchanger.

23. The computer system of claim 16, further comprising the working fluid, wherein the working fluid is a refrigerant.

24. The computer system of claim 16, further comprising the working fluid, wherein the working fluid is a refrigerant having a boiling point in the heat exchanger between about 50° F. and about 65° F.

25. The computer system of claim 16 wherein the heat exchanger is positioned upstream of the first computer module compartment in the chassis.

26. A computer system comprising:
a chassis;
a first computer module compartment positioned in the chassis and in an air flow path;
a first heat exchanger positioned in the chassis and in the air flow path, wherein the first heat exchanger includes at least one internal fluid passage configured to carry a working fluid that absorbs heat from air flowing in the air flow path; and
a second heat exchanger in fluid communication with the first heat exchanger, wherein the second heat exchanger is configured to cool the working fluid carried by the first heat exchanger.

27. The computer system of claim 26, further comprising the working fluid, wherein the working fluid has a boiling point in the first heat exchanger between about 45° F. and about 75° F.

28. The computer system of claim 26, further comprising a plurality of computer modules held in the first computer module compartment.

29. The computer system of claim 26, further comprising a second computer module compartment positioned in the chassis and in the air flow path, wherein the first heat exchanger is positioned at least partially between the first and second computer module compartments.

30. The computer system of claim 26 wherein the second heat exchanger is spaced apart from the chassis.

31. The computer system of claim 26, further comprising a controller operably coupled to the second heat exchanger to maintain the working fluid in phase transition within the first heat exchanger.

32. The computer system of claim 26 wherein the first computer module compartment is configured to hold a plurality of computer modules oriented edgewise with respect to the air flow path.

33. A computer system comprising:
a chassis;
an air mover positioned in flow communication with the chassis, wherein the air mover is configured to move air along a flow path through at least a portion of the chassis;
a first computer module compartment positioned in the air flow path in the chassis;
a first plurality of computer modules held in the first computer module compartment at least partially in the air flow path;
a second computer module compartment positioned in the air flow path in the chassis and spaced apart from the first computer module compartment;
a second plurality of computer modules held in the second computer module compartment at least partially in the air flow path; and
a heat exchanger positioned in the air flow path in the chassis, wherein the heat exchanger is positioned at least partially downstream of the first computer module compartment and at least partially upstream of the second computer module compartment, and wherein the heat exchanger includes at least one opening through which the air mover moves air.

34. The computer system of claim 33 wherein the air mover is positioned toward an upper portion of the chassis and configured to draw air upward through the chassis and past the first computer module compartment, the heat exchanger, and the second computer module compartment.

35. The computer system of claim 33 wherein the air mover is positioned toward a bottom portion of the chassis and configured to drive air through the chassis and past the first computer module compartment, the heat exchanger, and the second computer module compartment.

36. The computer system of claim 33 wherein the air mover is carried by the chassis.

37. The computer system of claim 33 wherein the heat exchanger is a first heat exchanger, and wherein the computer system further comprises:
a third computer module compartment positioned in the air flow path in the chassis and spaced apart from the second computer module compartment;
a third plurality of computer modules held in the third computer module compartment at least partially in the air flow path; and
a second heat exchanger positioned in the air flow path in the chassis, wherein the second heat exchanger is positioned at least partially downstream of the second computer module compartment and at least partially upstream of the third computer module compartment, and wherein the heat exchanger includes at least one opening through which the air mover moves air.

38. The computer system of claim 33 wherein the air mover, the first computer module compartment, the second computer module compartment, and the heat exchanger are arranged vertically with respect to the chassis.

39. The computer system of claim 33 wherein the first computer module compartment is configured to hold the first plurality of computer modules in edgewise orientation with respect to the air flow path toward a first side of the heat exchanger, and wherein the second computer module compartment is configured to hold the second plurality of computer modules in an edgewise orientation with respect to the air flow path toward a second side of the heat exchanger opposite to the first side of the heat exchanger.

40. The computer system of claim 33 wherein each of the first plurality of computer modules is individually carried by the first computer module compartment, wherein each of the first plurality of computer modules includes at least a first computer processor, wherein each of the second plurality of computer modules is individually carried by the second computer module compartment, and wherein each of the second plurality of computer modules includes at least a second computer processor.

41. The computer system of claim 33 wherein the heat exchanger includes at least one internal fluid passage configured to carry a working fluid.

42. The computer system of claim 33 wherein the heat exchanger includes at least one internal fluid passage configured to carry a working fluid having a boiling point in the heat exchanger between about 45° F. and about 75° F.

43. The computer system of claim 33 wherein each computer module of the first and second pluralities of computer modules includes at least one processor.

44. A method for cooling first and second computer modules positioned in a chassis, the method comprising:
moving a portion of air past the first computer module in the chassis to transfer heat from the first computer module to the portion of air;
after moving the portion of air past the first computer module, moving the portion of air past a heat exchanger in the chassis to transfer heat from the portion of air to the heat exchanger; and
after moving the portion of air past the heat exchanger, moving the portion of air past the second computer module in the chassis to transfer heat from the second computer module to the portion of air.

45. The method of claim 44 wherein the heat exchanger is a first heat exchanger, and further comprising:
after moving the portion of air past the second computer module, moving the portion of air past a second heat exchanger in the chassis to transfer heat from the portion of air to the second heat exchanger; and
after moving the portion of air past the second heat exchanger, moving the portion of air past a third computer module in the chassis to transfer heat from the third computer module to the portion of air.

46. The method of claim 44 wherein moving a portion of air past the first computer module includes moving a portion of air past a first plurality of computer modules arranged in parallel in the chassis, and wherein moving the portion of air past the second computer module includes moving the portion of air past a second plurality of computer modules arranged in parallel in the chassis.

47. The method of claim 44 wherein moving the portion of air past a heat exchanger includes moving the portion of air through an opening in the heat exchanger.

48. The method of claim 44, further comprising moving a working fluid through an internal passage in the heat exchanger, wherein moving the portion of air past the heat exchanger includes transferring heat to the working fluid.

49. The method of claim 44, further comprising moving a working fluid through an internal passage in the heat exchanger, wherein moving the portion of air past the heat exchanger includes transferring heat to the working fluid to boil at least a portion of the working fluid in the internal passage.

50. The method of claim 44, further comprising moving a working fluid having a boiling point between about 45° F. and about 75° F. through an internal passage in the heat exchanger, wherein moving the portion of air past the heat exchanger includes transferring heat to the working fluid.

51. A method for dissipating heat generated by a computer module in a chassis, the method comprising:
moving a portion of air past the computer module in the chassis to transfer heat from the computer module to the portion of air;
moving a working fluid through an internal passage of a heat exchanger positioned in the chassis; and
moving the portion of air past the heat exchanger to transfer heat from the portion of air to the heat exchanger and boil at least a portion of the working fluid in the internal passage.

52. The method of claim 51 wherein moving a working fluid through an internal passage of a heat exchanger includes moving a working fluid having a boiling point between about 45° F. and about 75° F.

53. The method of claim 51 wherein moving a working fluid through an internal passage of a heat exchanger includes moving a working fluid having a boiling point between about 50° F. and about 65° F.

54. The method of claim 51 wherein the computer module is a first computer module, and wherein the method further comprises, after moving the portion of air past the heat exchanger, moving the portion of air past a second computer module in the chassis to transfer heat from the second computer module to the portion of air.

55. The method of claim 51 wherein the computer module is a first computer module, the working fluid is a first working fluid, and the heat exchanger is a first heat exchanger having a first internal passage, and wherein the method further comprises:
after moving the portion of air past the first heat exchanger, moving the portion of air past a second computer module in the chassis to transfer heat from the second computer module to the portion of air;
moving a second working fluid through a second internal passage of a second heat exchanger positioned at least proximate to the second computer module in the chassis; and
moving the portion of air past the second heat exchanger to transfer heat from the portion of air to the second heat exchanger and boil at least a portion of the second working fluid in the second internal passage.

56. The method of claim 55 wherein moving the first working fluid through the first internal passage includes moving a first portion of a refrigerant received from a refrigerant source, and wherein moving a second working fluid through a second internal passage includes moving a second portion of the refrigerant received from the refrigerant source.

57. A method for dissipating heat generated by a computer module in a chassis, the method comprising:
moving a portion of air past the computer module in the chassis to transfer heat from the computer module to the portion of air;
moving a working fluid through an internal passage of a heat exchanger positioned in the chassis;
moving the portion of air past the heat exchanger to transfer heat from the portion of air to the working fluid; and
controlling the working fluid to maintain the working fluid at least proximate to the phase transition state while flowing through the internal passage.

58. The method of claim 57 wherein moving a working fluid through an internal passage of a heat exchanger includes moving a working fluid having a boiling point between about 45° F. and about 75° F.

59. The method of claim 57 wherein moving a working fluid through an internal passage of a heat exchanger includes moving a working fluid having a boiling point between about 50° F. and about 65° F.

60. The method of claim 57 wherein the computer module is a first computer module, and wherein the method further comprises, after moving the portion of air past the heat exchanger, moving the portion of air past a second computer module in the chassis to transfer heat from the second computer module to the portion of air.

61. The method of claim 57 wherein controlling the working fluid to maintain the working fluid at least proximate to the phase transition state includes controlling the pressure of the working fluid.

62. A system for cooling first and second computer modules positioned in a chassis, the system comprising:
means for moving a portion of air past the first computer module in the chassis to transfer heat from the first computer module to the portion of air;
means for moving the portion of air past a heat exchanger in the chassis after moving the portion of air past the first computer module; and
means for moving the portion of air past the second computer module in the chassis after moving the portion of air past the heat exchanger.

63. The system of claim 62 wherein the heat exchanger is a first heat exchanger, and further comprising:
means for moving the portion of air past a second heat exchanger in the chassis after moving the portion of air past the second computer module; and
means for moving the portion of air past a third computer module in the chassis after moving the portion of air past the second heat exchanger.

64. The system of claim 62 wherein the means for moving the portion of air past a heat exchanger includes means for moving the portion of air through an opening in the heat exchanger.

65. The system of claim 62, further comprising means for moving a working fluid through an internal passage in the heat exchanger.

66. The system of claim 62, further comprising means for moving a working fluid having a boiling point between about 45° F. and about 75° F. through an internal passage in the heat exchanger.

67. A computer system comprising:
means for positioning at least a first computer module in a first position along an air flow path;
means for positioning at least a second computer module in a second position along the air flow path;
means for moving a portion of air along the air flow path; and
means for removing heat from the portion of air, wherein the means for removing heat are positioned at least partially between the first computer module and the second computer module along the air flow path.

68. The computer system of claim 67 wherein the means for positioning at least a first computer module includes means for positioning a first plurality of computer modules at least proximate to the air flow path, and wherein the means for positioning at least a second computer module includes means for positioning a second plurality of computer modules at least proximate to the air flow path.

69. The computer system of claim 67 wherein the means for removing heat from the portion of air includes means for moving a working fluid through a passage positioned at least proximate to the air flow path.

70. The computer system of claim 67 wherein the means for removing heat from the portion of air includes means for boiling a working fluid moving through a passage positioned at least proximate to the air flow path.

71. The computer system of claim 67 wherein the means for removing heat from the portion of air includes means for moving a working fluid through a passage positioned at least proximate to the air flow path, wherein a first portion of the working fluid is in a liquid state and a second portion of the working fluid is in a gaseous state.
